(19) United States
(12) Patent Application Publication
(10) Pub. No.: US 2025/0092523 A1
(43) Pub. Date: Mar. 20, 2025

(54) A REACTOR

(71) Applicant: TOBB EKONOMI VE TEKNOLOJI UNIVERSITESI, Ankara (TR)

(72) Inventors: Zarife Goknur BUKE, Ankara (TR); Omer Refet CAYLAN, Ankara (TR); Tarik Can TURKOGLU, Ankara (TR)

(21) Appl. No.: 18/729,255

(22) PCT Filed: Jan. 18, 2023
(86) PCT No.: PCT/TR2023/050038

§ 371 Date: Jul. 16, 2024

(30) Foreign Application Priority Data
Jan. 24, 2022 (TR) 2022/000837

(51) Int. Cl. C23C 16/46; C23C 16/44

(52) U.S. Cl. CPC C23C 16/46; C23C 16/4409; C23C 16/4411

(57) ABSTRACT

Disclosed is a reactor that uses chemical vapor deposition methods, and in particular, is used for the synthesis of micro and nano-sized materials, growth of nanomaterials, material coating and shaping materials.

### FIELD OF THE INVENTION

The present invention relates to a reactor that uses chemical vapor deposition method, in particular, is used for the synthesis of micro and nano-sized materials, one and two dimensional materials, material coating and shaping materials.

### PRIOR ART

Chemical vapor deposition reactors are used in applications involving the deposition of a substance or layers of atoms onto a surface. In particular, chemical vapor deposition reactor is used in industrial production, R&D processes, micro and nano-material synthesis, growth of nanomaterials, material coating and in some cases for shaping materials.

There are different types of chemical vapor deposition; “low-pressure chemical vapor deposition reactor” and “atmospheric pressure chemical vapor deposition reactor”. If a vacuum pump and gauge are added to the atmospheric pressure chemical vapor deposition reactor, a low-pressure chemical vapor deposition reactor is obtained.

Chemical vapor deposition reactors have a body. There is a chamber located in the inner part of the body for placing the samples to be deposited. There are heat sources around the mentioned chamber. Heat sources heat the chamber where the samples are located at the center of the chamber. Flanges are used to access the inside of the chamber for placing the samples. Moreover, there are holes on the flanges so that the gases can be delivered into the chamber. The size and shapes of the mentioned chamber may vary. Nano or micro size coating or growth process is carried out by chemical vapor deposition process on the materials placed inside the chamber.

In an application in the state of the art, fixed chamber chemical vapor deposition reactors are used. The chamber in which the growth is accomplished fixed to the reactor. Since the chamber is fixed, this prevents the coating process in the chamber from being homogeneous. The coatings deposited in the mentioned application have different thicknesses in different regions. Since the deposition is not homogeneous, this has negative effects on the quality of the coating.

In another application in the state of the art, chemical vapor deposition reactors are used, the chamber of which is placed inside the furnace.

As explained above, there are some important problems in the state of the art for reactors used for chemical vapor deposition. The biggest challenge caused by these reactors is that a homogeneous coating cannot be synthesized on the surface of the material in the chamber. The mentioned problem causes cost and time loss for industrial production and research processes. It is critical to achieve homogeneous production by chemical vapor deposition method.

A furnace consisting of two parts and a chemical vapor deposition reactor with a chamber positioned between the mentioned two parts is put forth with the present invention. The chamber is rotated by transferring the motion of the engine to the flange mounted on a bearing with the help of a belt. A reactor that provides a more homogeneous coating by rotating the chamber is developed compared to the state of the art.

### Aims of the Invention

The aim of the present invention is to develop a furnace consisting of two parts and a reactor positioned between the two parts of the furnace, containing a chamber used to carry out the chemical vapor deposition.

Another aim of the present invention is to develop a reactor containing a chamber in which chemical vapor deposition is carried out, providing more homogeneous coatings with its rotational movement.

Another aim of the present invention is to develop a cost-effective chemical vapor deposition reactor that provides motion transmission and rotation of the chamber using a belt-pulley system.

Another aim of the present invention is to develop a reactor with a chamber in which different materials can be coated by using the chemical vapor deposition method.

Another aim of the present invention is to develop a reactor with a chamber with holes used for the chemical vapor deposition and used to carry the gases required for the reaction or the reaction system into the chamber.

### BRIEF DESCRIPTION OF THE INVENTION

The present invention is used for synthesis/coating by chemical vapor deposition and is particularly suitable for synthesis/coating in micro-nano sizes.

The reactor is constituted by a chamber that is placed inside a heater consisting of two parts and a movement mechanism that enables this chamber to rotate around its own axis.

A reactor as defined in the first claim and other dependent claims, developed to achieve the aim of the present invention, comprises of the following; a heater, a first body forming part of the heater; a handle used to move the first body; a second body forming the other part of the heater; at least one button positioned on the surface of the second body; an insulating member surrounding the first body and the second body; a flexible member between the first body and the second body; a body lock securing the first body and the second body to each other; roller bearing; at least one bearing enabling rotation of the chamber; at least one chamber in which chemical vapor deposition is carried out; a first flange positioned at one end of the chamber; a first hole in the first flange surface; a second flange closing one end of the chamber; a second hole in the second flange surface; a lock used to secure the first flange or the second flange with the chamber, a step in the form of a recess or protrusion towards the interior of the receptacle; an engine that rotates the chamber by converting energy into mechanical work; a motion mechanism positioned between the engine and the bearing.

The developed reactor for the chemical vapor deposition method has two most important technical advantages. The first of these advantages is that the chamber, which is heated during production, cools quickly and the access to the chamber is easy. The technical features that provide this advantage are as follows. The heater of the reactor consists of two parts. These parts are the first body and the second body. The first body and the second body are positioned parallel to each other. The chamber is seated between the first body and the second body. The first body is moved away from the second body. This ensures easy access to the chamber and allows the chamber to cool quickly.

Another important advantage provided by the reactor for the chemical vapor deposition method, is the homogeneous synthesis/coating. The technical features that provide this advantage are as follows. The chamber is seated on bearings at both ends. An engine rotates a pulley by transforming energy into work. The pulley is connected to the bearing with a belt. The rotational movement of the pulley is transmitted to the bearing with the help of the belt and the bearing rotates. The rotational movement of the bearing causes the chamber to rotate around itself. The material in the chamber is constantly mixed with the effect of the rotational movement of the chamber and the gravity. Thus, a reactor that performs homogeneous synthesis/coating is achieved by using the chemical vapor deposition method.

### DETAILED DESCRIPTION OF THE INVENTION

A reactor developed to achieve the aim of the present invention is shown in the attached figures, in which;

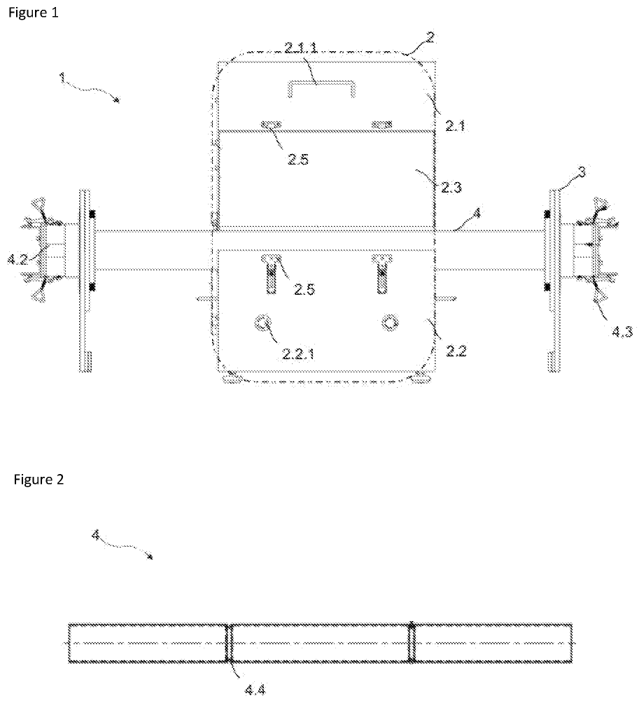

FIG. 1. A front view of the reactor.

FIG. 2. A front view of the chamber of the reactor.

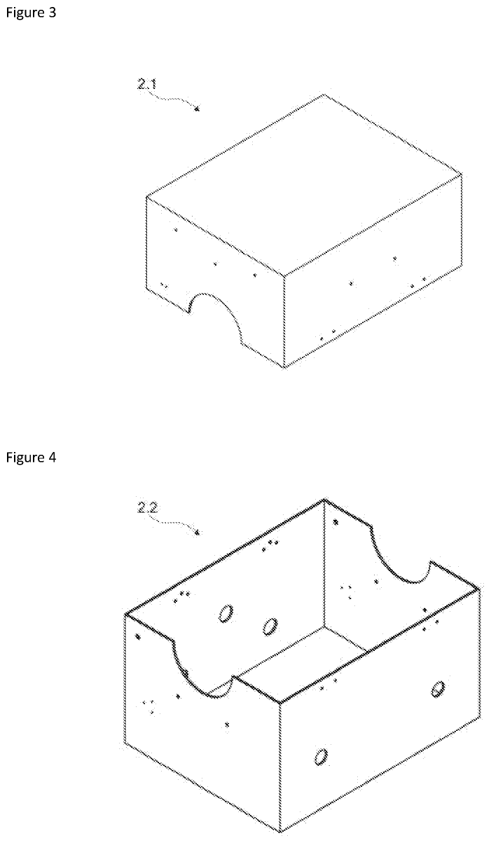

FIG. 3. A perspective view of the first body of the reactor.

FIG. 4. A perspective view of the second body of the reactor.

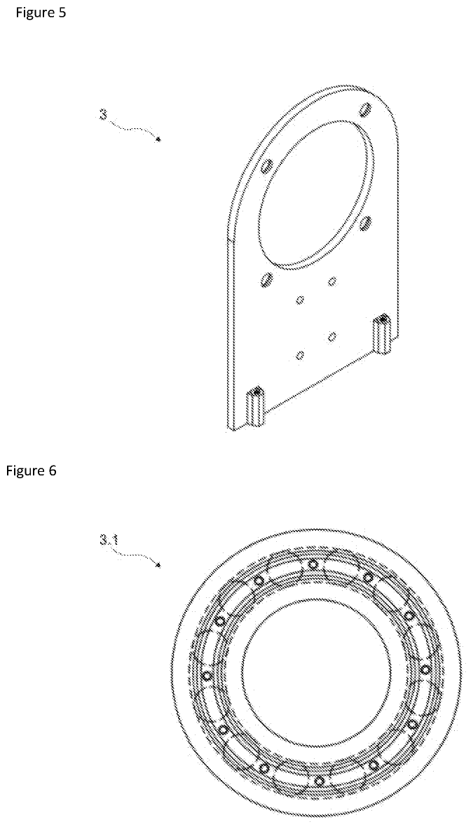

FIG. 5. A perspective view of the bearing housing of the reactor.

FIG. 6. A perspective view of the bearing of the reactor.

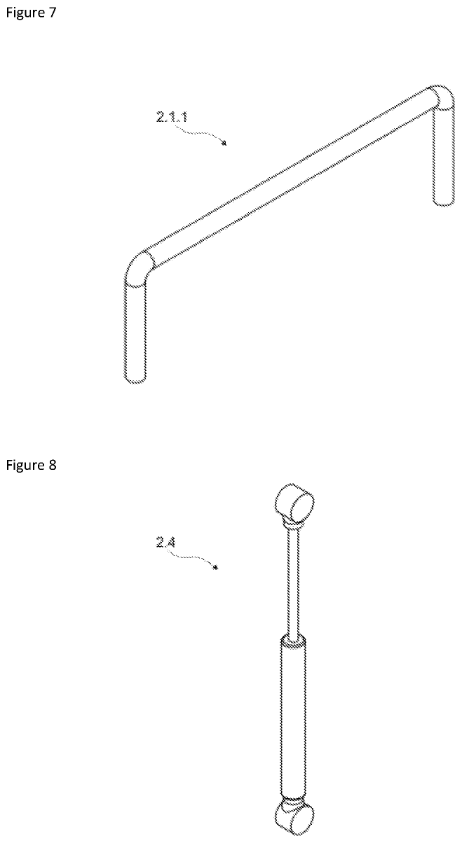

FIG. 7. A perspective view of the handle of the reactor.

FIG. 8. A perspective view of the flexible element of the reactor.

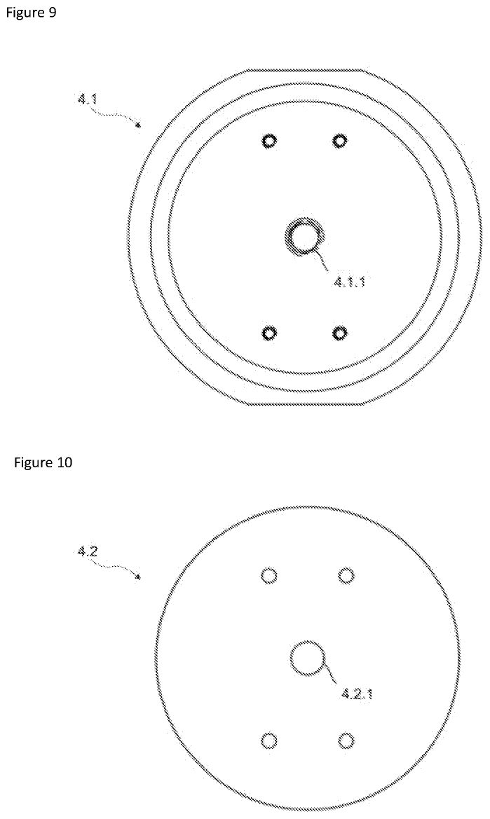

FIG. 9. A front view of the first flange of the reactor.

FIG. 10. A front view of the second flange of the reactor.

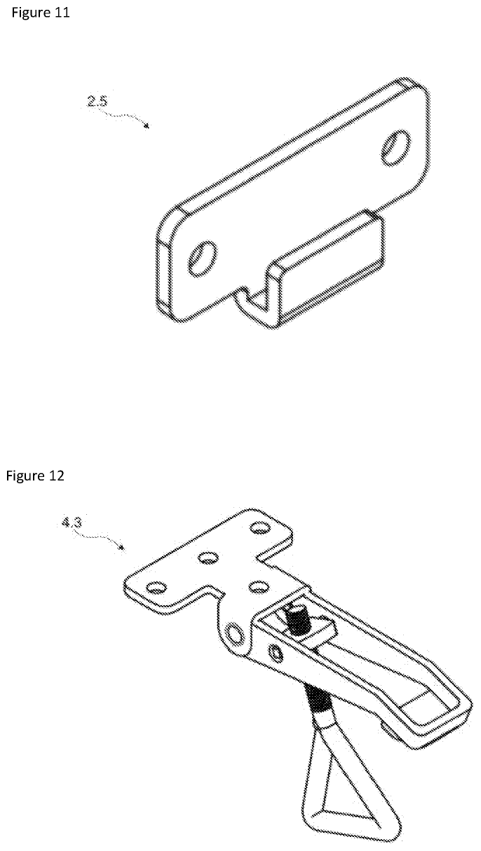

FIG. 11. A perspective view of the body lock hook of the reactor.

FIG. 12. A perspective view of the lock of the reactor.

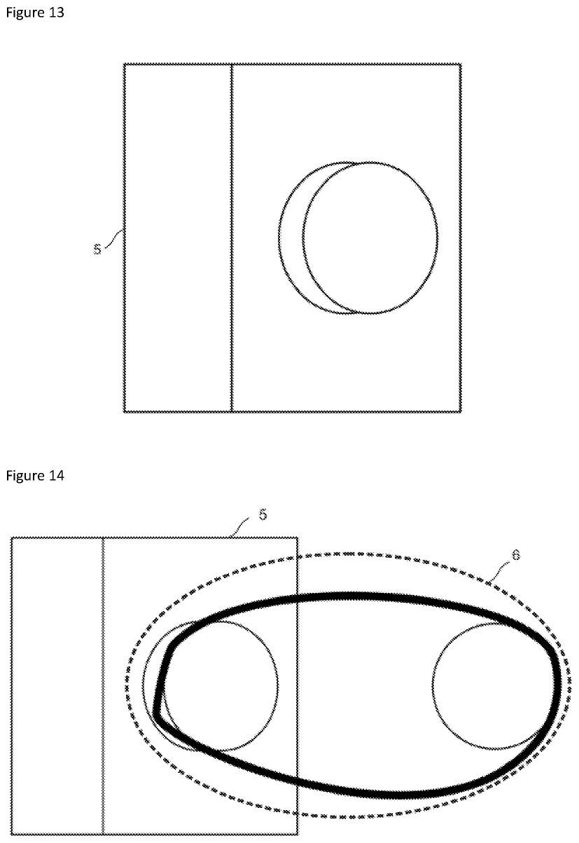

FIG. 13. A perspective view of the engine of the reactor.

FIG. 14. A perspective view of the engine and the motion mechanism of the reactor.

The parts in the figure are enumerated one by one and the parts correspond to these numbers are given in the following.
1. Reactor
2. Heater
   2.1. First body
      2.1.1. Handle
   2.2. Second body
      2.2.1. Button
   2.3. Insulating element
   2.4. Flexible element
   2.5. Body lock
3. Bearing housing
   3.1. Bearing
4. Chamber
   4.1. First flange
      4.1.1. First hole
   4.2. Second flange
      4.2.1. Second hole
   4.3. Lock
   4.4. Step
5. Engine
6. Motion mechanism

The present invention which is used for homogeneous material synthesis and coating by chemical vapor deposition method, especially in micro-nano size production areas, comprises of the following;
at least one chamber (4) in chemical vapor deposition is carried out, which is capable of rotating clockwise or counterclockwise along its own axis, provides homogeneity by mixing the substances therein with the effect of gravity and rotational movement,
at least one heater (2) which consists of a first body (2.1) and a second body (2.2) positioned parallel to the first body (2.1) so as to provide rapid cooling and heat control and also which provides the necessary heat for the deposition from chemical vapor to take place in the chamber (4) positioned between the first body (2.1) and the second body (2.2), and transfers this heat to the chamber (4).

The reactor (1) is used in industry, research, and development centers, in areas where large and small-scale production is carried out, especially for the synthesis of micro and nano-sized materials and for material coating processes by using the chemical vapor deposition method.

The reactor (1) preferably consists of five parts. The mentioned parts are the heater (2), the bearing housing (3), the chamber (4), the engine (5) and the motion mechanism (6). While material synthesis, and material coating processes are carried out, the chemical vapor deposition method is one of the most preferred methods. The reactor (1) is used for material synthesis, material synthesis on a substrate and material coating processes. The reactor (1) uses the chemical vapor deposition method during production.

The heater (2) is made of preferably ceramic or metal materials. The mentioned heater (2) provides the necessary heat for the chemical vapor deposition. The heater (2) transforms the power taken from the energy source into heat. In its most basic form, the heater (2) consists of the first body (2.1), the second body (2.2), the insulation element (2.3) and the flexible element (2.4). In the preferred application of the invention, the furnace is used as the heater (2).

The first body (2.1) is preferably in the form of a rectangular prism and is made of metal materials. The first body (2.1) forms a part of the heater (2). The first body (2.1) is used to meet the heat required for chemical vapor deposition. At the same time, the first body (2.1) is used to house all other elements such as control panel, electrical circuit. The first body (2.1) preferably includes at least one handle (2.1.1).

The handle (2.1.1) is positioned on the upper surface of the first body (2.1). The handle (2.1.1) is used to move the first body (2.1) back and forth, especially in the direction of the second body (2.2). The shape and thickness of the handle (2.1.1) may vary. The handle (2.1.1) is preferably manufactured from metal materials. The handle (2.1.1) is fixed to the first body (2.1) with the help of a fastener or by methods such as welding and riveting. In the preferred application of the invention, there is at least one handle (2.1.1) in the form of “U”.

The second body (2.2) is preferably made of materials with high electrical conductivity, such as metal. The second body (2.2) is positioned from one surface parallel to one surface of the first body (2.1). The second body (2.2) is preferably used to meet the heat required for chemical vapor deposition. The second body (2.2) preferably includes at least one button (2.2.1). In the preferred embodiment of the invention, the first body (2.1) is positioned on the second body (2.2). The second body (2.2) and the first body (2.1) are fixed to each other with the help of hinges.

The button (2.2.1) is located on a surface of the second body (2.2) and is used to control the device. The button (2.2.1) is used to control the reactor (1) so as to control actions such as turning on and off. The shape and type of the button (2.2.1) may vary according to the preferred application. The button (2.2.1) can be of different types such as push-pull, keyed or rotary. In the preferred embodiment of the invention, there are two buttons (2.2.1), one on and one off.

The insulating element (2.3) is used to protect the heat generated in the interior of the heater (2) and to prevent the heat from being transferred from the heater (2) to the environment. The mentioned insulating element (2.3) is located along all inner surfaces of the first body (2.1) and preferably the second body (2.2). In the preferred embodiment of the invention, ceramic fiber plate is used as the insulating element (2.3).

The flexible element (2.4) is positioned between the first body (2.1) and the second body (2.2). The flexible element (2.4) is used to control the approaching and deviation of the first body (2.1) and the second body (2.2). The flexible element (2.4) is preferably fixed at one end to a surface of the first body (2.1) and from the other end to a surface of the second body (2.2). The flexible element (2.4) compresses and stretches, causing the first body (2.1) and the second body (2.2) to get closer and further apart from each other. In the preferred embodiment of the invention, a shock absorber is used as a flexible element (2.4).

The body lock (2.5) is positioned on the surface parallel to the surface where the hinges that enable the first body (2.1) and the second body (2.2) to be joined to each other, are located. The body lock (2.5) is used to keep the first body (2.1) and the second body (2.2) fixed and is used to prevent the first body (2.1) from moving away from the second body (2.2) in an undesired situation. A part of the mentioned body lock (2.5) is on the first body (2.1) surface, and the other part is on the second body (2.2) surface. When the first body (2.1) is closed on the second body (2.2), the body lock (2.5) parts get closer to each other. The locking is carried out with the help of the body lock (2.5) and the first body (2.1) and the second body (2.2) are fixed to each other. In the preferred embodiment of the invention, tension lock is used as the body lock (2.5).

In the preferred embodiment of the invention, the first body (2.1) is positioned on the second body (2.2). The part that carries the weight of the reactor (1) is the second body (2.2). The first body (2.1) is connected to the second body (2.2) using at least one flexible member (2.4). In the mentioned embodiment, the flexible element (2.4) is fixed from one end to the side surface of the second body (2.2) and from the other end to the side surface of the first body (2.1). In case the flexible element (2.4) is compressed, the first body (2.1) and the second body (2.2) contact each other along all the edges of their parallel surfaces. The first body (2.1) can be moved along the movement direction of the flexible element (2.4) with the help of the handle (2.1.1) thereon. Thus, the opening between the first body (2.1) and the second body (2.2) is controlled.

The first body (2.1) and the second body (2.2) have a semi-circular opening on their side surfaces to be symmetrical to each other. In case the flexible element (2.4) is compressed, the parallel surfaces of the first body (2.1) and the second body (2.2) close on each other. The semicircular forms in the first body (2.1) and the second body (2.2) overlap each other, thus forming an opening in the form of a circle. The mentioned opening is used so as to position the chamber (4) between the first body (2.1) and the second body (2.2).

The bearing housing (3) is used to house the bearing (3.1) and to position the chamber (4). The height of the bearing housing (3) can vary according to the preferred application. The bearing housing (3) comprises at least one bearing (3.1). In the preferred embodiment of the invention, there are at least two bearing housings (3). The heater (2) is positioned between the bearing housings (3) which are positioned parallel to each other. There is a distance between each bearing housing (3) and the heater (2). The mentioned distance may vary depending on the material from which the bearing housing (3) is produced, the length of the chamber (4) and the temperature of the heater (2).

The bearing (3.1) is used preferably on the upper part of the bearing housing (3) so as to position the chamber (4) and to perform the rotational movement of the chamber (4). The bearing (3.1) has a rotating structure. The size of the bearing (3.1) may vary depending on the size of the chamber (4) to be used. In the preferred embodiment of the invention, a total of two bearings (3.1) are used, one in each bearing housing (3).

The chamber (4) is in a cylindrical form and is preferably manufactured from materials such as metal with high thermal conductivity and physical strength. The chamber (4) can be defined in the form of a tube. There is a space inside the chamber (4). The length of the chamber (4) varies. The chamber (4) fits into the bearings (3.1) from both ends of the cylindrical form. Bearing housings (3) position the chamber (4) at the height of the middle part of the heater (2). The chamber (4) is placed between the first body (2.1) and the second body (2.2) by passing through the openings in the first body (2.1) and the second body (2.2). The circular openings in the first body (2.1) and the second body (2.2) are closed with the chamber (4), and the first body (2.1) and the second body (2.2) provides a closed form. The opening inside the chamber (4) is the place where the chemical vapor deposition takes place. The materials to be coated are placed inside the chamber (4). The chamber (4) rotates around its own axis. The heater (2) heats the chamber (4) in a 360° cylindrical manner. Chamber (4) comprises at least one first flange (4.1), at least one second flange (4.2), at least one lock (4.3), and at least one step (4.4). In the preferred embodiment of the invention, the chamber (4) is made of quartz tube.

The first flange (4.1) is positioned at the end of the chamber (4). The first flange (4.1) provides access to the interior of the chamber (4) by opening and closing the same. The first flange (4.1) is preferably manufactured from materials with high physical strength, such as metal and polymer. The first flange (4.1) closes the opening at the end of the chamber (4) along its length. The first flange (4.1) is opened to access the inside of the chamber (4) and the first flange (4.1) is closed to prevent the materials inside the chamber (4) from coming out of the chamber (4).

The first flange (4.1) is used to load the sample into the chamber (4). The first flange (4.1) includes at least one first hole (4.1.1) used to allow the gas required for the reaction to pass into the chamber (4).

In another embodiment of the invention, electronic modules and valves capable of mass flow control are provided with the first flange (4.1) for the controlled transport of gases into the chamber (4).

The first hole (4.1.1) is drilled in the surface of the first flange (4.1). The first hole (4.1.1) is in the form of an opening. The size and diameter of the first hole (4.1.1) may vary depending on the connection to be used. The number of the first hole (4.1.1) to be used varies according to the number of connections to be made. The first hole (4.1.1) serves as a passage to provide material passage to the interior of the chamber (4). In the preferred embodiment of the invention, the first hole (4.1.1) is used to provide various pneumatic connections.

The second flange (4.2) is positioned at the end of the chamber (4). The second flange (4.2) provides access to the interior of the chamber (4) by opening and closing the same. The second flange (4.2) and the first flange (4.1) are preferably manufactured from materials such as light metal and polymer with high physical strength, which will not be affected by the gases used. The second flange (4.2) closes the opening at the end of the chamber (4) along its length. The second flange (4.2) is opened to access the inside of the chamber (4) and the second flange (4.2) is closed to prevent the materials inside the chamber (4) from coming out of the chamber (4). At the same time, the gas atmosphere inside is controlled by closing both flanges. The second flange (4.2) is used to remove the sample from the chamber (4) after the chemical vapor deposition is carried out. The second flange (4.2) includes at least one second hole (4.2.1) used to transfer the waste gases formed as a result of the reaction to the outside of the chamber (4).

The second hole (4.2.1) is positioned on the surface of the second flange (4.2). The size and diameter of the second hole (4.2.1) may vary depending on the connection to be used. The number of the second hole (4.2.1) to be used varies according to the number of connections to be made. The second hole (4.2.1) serves as a passage to provide material passage from the interior of the chamber (4) to the outside of the chamber (4). In the preferred embodiment of the invention, the second hole (4.2.1) is used to provide various pneumatic connections. The second hole (4.2.1) is used to transfer the waste gases formed as a result of the reaction to the outside of the chamber (4).

The lock (4.3) is positioned at the end of the chamber (4). The lock (4.3) is used to hold the chamber (4) and the first flange (4.1) and the chamber (4) and the second flange (4.2) together in a stable manner. While accessing the chamber (4), the lock (4.3) is opened, releasing the first flange (4.1) and the second flange (4.2). In the preferred embodiment of the invention, a total of four locks (4.3) are used, two for the first flange (4.1) and two for the second flange (4.2). In said embodiment, tension lock is used as the lock (4.3).

The step (4.4) is in the form of a protrusion-recess that extends from the surface of the chamber (4) in the central direction of the chamber (4), perpendicularly cutting the long surface of the chamber (4) positioned in the middle of the long surface of the chamber (4). The step (4.4) prevents the powders, samples placed in the chamber (4) from moving inside the chamber (4). The chamber (4) is longer than the heater (2) and the progress of the sample to the parts of the chamber (4) that are not in contact with the heater (2) causes heat loss. Step (4.4) is used to prevent heat losses that may occur due to the progress of the sample in the chamber (4). In a different embodiment of the invention, the section of the cylindrical form of the chamber (4) is narrowed in some parts to form a step (4.4).

The engine (5) generates the work required for the chamber (4) to make the rotational movement. The engine (5) provides the rotation of the chamber (4) with the power from an energy source. In the preferred embodiment of the invention, the engine (5) rotates a pulley with the generated energy.

The motion mechanism (6) is used to transmit the work generated by the engine (5) to the bearings (3.1) and to enable the chamber (4) to rotate around its own axis.

The motion mechanism (6) is positioned between the engine (5) and the bearings (3.1). The motion mechanism (6) rotates the bearings (3.1) and the chamber (4), which is placed on the rotating bearings (3.1), rotates around its own axis. In the preferred embodiment of the invention, belt-pulley system is used as the motion mechanism (6).

In the preferred embodiment of the invention, the rotation of the chamber (4) around its axis is provided as follows. The two bearing housings (3) with the bearing (3.1) on the top are aligned with each other. The chamber (4) is seated on the bearings (3.1). The engine (5) is started. The motor (5) rotates a pulley. The pulley and the bearing (3.1) are connected to each other by means of a belt. The rotational movement of the pulley is transferred to the bearing (3.1) by the belt. The bearings (3.1) start to rotate and the chamber (4) seated on the bearings (3.1) rotates on its own axis.

The operation of the reactor (1) in one embodiment is as follows. Bearing housings (3) are aligned on both sides of a heater (2) consisting of a first body (2.1) and a second body (2.2). The first body (2.1) and the second body (2.2) are moved away from each other by moving the first body (2.1) upwards with the help of the handle (2.1.1). Then, the first flange (4.1) at one end of the chamber (4) is opened, and the sample to be coated or used as a substrate is placed inside the chamber (4). After the sample is placed, the first flange (4.1) is closed and fixed to the chamber (4) with the lock (4.3). The chamber (4) is seated in the semicircular openings in the second body (2.2). Then, the chamber (4) fits into the bearings (3.1) from both ends. The first body (2.1) is brought closer to the second body (2.2) with the help of the handle (2.1.1). The openings of the first body (2.1) and the second body (2.2) surround the chamber (4). Locking is carried out with the body lock (2.5) so as not to move the first body (2.1) and the second body (2.2) away from each other. The chamber (4) is seated on the bearings (3.1) from both ends. After the chamber (4) is seated on the bearings (3.1), the necessary connections for the first hole (4.1.1) and the second hole (4.2.1) are provided. The heater (2) and the engine (5) is started.

The heater (2) heats the chamber (4) for 360°. The operation of the engine (5) rotates the pulley and the rotational movement is transmitted to the bearings (3.1) by means of a belt. The materials in the chamber (4) are mixed continuously with the help of the rotational movement and gravity of the chamber (4). The substance is transferred into the chamber (4) with the help of the first hole (4.1.1). Precipitation from chemical steam is carried out with the effect of temperature. Continuous mixing of the sample in the chamber (4) ensures that the precipitation from chemical steam is carried out in a homogeneous manner. The waste gases seen during and after the reaction are transferred out of the chamber (4) with the help of the second hole (4.2.1). The body lock (2.5) is released after the production/plating process is completed. The first body (2.1) is moved away from the second body (2.2). Moving the first body (2.1) away from the second body (2.2) ensures rapid cooling of the chamber (4), which is heated during production. The second flange (4.2) positioned at one end of the chamber (4) is removed and the produced/coated sample is removed from the chamber (4). Thus, a reactor (1) that can make production/coating homogeneously with the chemical vapor deposition method is realized.

1. A reactor which is used for homogeneous material production and coating by chemical vapor deposition method, especially in micro-nano size synthesis field, the reactor comprising;
at least one chamber in which the chemical vapor deposition is carried out, which is capable of rotating clockwise or counterclockwise along its own axis, provides homogeneity by mixing the substances therein with the effect of gravity and rotational movement; and
at least one heater which comprises a first body and a second body positioned parallel to the first body to provide rapid cooling and heat control and also provides the necessary heat for the chemical vapor deposition to be carried out in the chamber positioned between the first body and the second body , and directs this heat to the chamber.

2. Reactor according to claim 1, comprising at least one handle which is positioned on one surface of the first body, is used to move the first body back and forth, especially to move the first body closer to and away from the second body.

3. Reactor according to claim 1, wherein at least one heater combined with the first body positioned parallel to the second body, where the first body and the second body are fixed to each other with the help of hinges.

4. Reactor according to claim 1, comprising at least one button which is positioned on one surface of the second body and is used to control the heater and the rotational movement of the chamber.

5. Reactor according to claim 1, comprising at least one insulating element which is used to preserve the heat created inside the heater and to prevent the heat from being transferred from the heater to the environment, and to ensure that the heat heats the chamber, is positioned on the inner surfaces of the first body and preferably the second body.

6. Reactor according to claim 1, comprising at least one flexible element which is fixed to a surface of the first body from one end and the second body from the other end, allows the first body and the second body to converge and move away from each other by compressing and stretching.

7. Reactor according to claim 1, wherein at least one heater through which the chamber passes, is located on two parallel surfaces of the first body and the second body, is in the form of a semicircle, and has at least one opening that acquires the form of a circle when the first body and the second body are completely in contact with each other.

8. Reactor according to claim 1, wherein at least one chamber which comprises at least one first flange, at least one second flange, at least one lock, and at least one step.

9. Reactor according to claim 8, wherein the at least one first flange which is located at the end of the chamber, closes the end of the chamber, and provides access to the interior of the chamber by opening and closing the same.

10. Reactor according to claim 8, wherein the at least one second flange which is located at the end of the chamber, closes the end of the chamber, and provides access to the interior of the chamber by opening and closing the same.

11. Reactor according to claim 8, comprising at least one first hole which is in the form of an opening positioned on the surface of the first flange, and is used to act as a passage to provide material passage to the interior of the chamber.

12. Reactor according to claim 8, comprising at least one second hole which is in the form of an opening positioned on the surface of the second flange, and is used to act as a passage to provide material passage to the interior of the chamber.

13. Reactor according to claim 8, comprising at least one lock which is positioned at the end of the chamber, is used to hold together the chamber and the first flange and the chamber and the second flange.

14. Reactor according to claim 1, comprising at least one step which is positioned between the ends of the long surface of the chamber, is in the form of a protrusion-recess that cuts the long surface of the chamber vertically, extending from the surface of the chamber in the direction of the interior of the chamber, is used to prevent the materials inside the chamber from moving.

15. Reactor according to claim 1, comprising at least one engine is used to produce the work required for the chamber to make the rotational movement.

16. Reactor according to claim 15, comprising at least one motion mechanism which is positioned between the engine and the bearings, is used to ensure that the chamber rotates around its own axis by transmitting the rotation created by the movement of the engine to the bearings.
